(19) United States
(12) Patent Application Publication
(10) Pub. No.: US 2019/0280665 A1
(43) Pub. Date: Sep. 12, 2019

(54) OUTPUT POWER STABILIZATION CIRCUIT AND HIGH OUTPUT AMPLIFIER DEVICE USING SAME

(71) Applicant: Mitsubishi Electric Corporation, Chiyoda-ku (JP)

(72) Inventor: Hiroyuki NONOMURA, Chiyoda-ku (JP)

(73) Assignee: Mitsubishi Electric Corporation, Chiyoda-ku (JP)

(21) Appl. No.: 16/313,989

(22) PCT Filed: Nov. 7, 2017
(86) PCT No.: PCT/JP2017/040022

§ 371 Date: Dec. 28, 2018

(30) Foreign Application Priority Data
Nov. 25, 2016 (JP) 2016-228560

(51) Int. Cl. H03G 3/30; H03F 1/32; H03F 3/189

(52) U.S. Cl. CPC H03G 3/3047; H03F 1/32; H03F 2200/387; H03F 2200/375; H03F 3/189

(57) ABSTRACT

An output power stabilization circuit includes: a first variable attenuator for attenuating a high-frequency signal inputted thereto; a second variable attenuator for attenuating the high-frequency signal outputted from the first variable attenuator; an output power detection circuit for monitoring the high-frequency signal outputted from the second variable attenuator and outputting an output power detection signal; a temperature monitoring circuit for outputting a temperature monitoring signal; a control circuit for outputting a first control signal for controlling the attenuation amount in the first variable attenuator and a second control signal for controlling the attenuation amount in the second variable attenuator, based on an output power setting signal and the temperature monitoring signal, by referring to previously stored table data; and an attenuation amount setting circuit for making comparison between the first control signal and the output power detection signal and outputting a first attenuation amount adjustment signal for adjusting the attenuation amount in the first variable attenuator.

### TECHNICAL FIELD

The present invention relates to an output power stabilization circuit for setting output power to a set value, and a high output amplifier device using the same.

### BACKGROUND ART

There has been a need for stably controlling power of high-frequency signals such as microwave signals, over wide dynamic ranges.

Conventionally, as pulse power stabilization control, there has been known controlling in such a way as to minimize errors between pulses while realizing changeovers to continuous-wave power stabilization control through adjustments of variable values in algorisms (refer to National Patent Publication No. 2012-531880 (PTL 1)).

### CITATION LIST

### Patent Literature

PTL 1: National Patent Publication No. 2012-531880

### SUMMARY OF INVENTION

### Technical Problem

Conventional pulse power stabilization control has been able to realize control with high accuracy, but has induced the problem of significant complicacy of a structure for performing controlling in such a way as to minimize errors between pulses and for performing adjustments of variable values in algorisms.

The present invention has been made in order to overcome the aforementioned problem and aims at providing an output power stabilization circuit capable of maintaining the output power of a high-frequency signal at a fixed value with high accuracy against temperature changes with a simple structure, and, also, providing a high output amplifier device using the output power stabilization circuit.

### Solution to Problem

An output power stabilization circuit and a high output amplifier device using the same according to the present invention includes: a first variable attenuator for attenuating a high-frequency signal inputted to an input terminal; a second variable attenuator for attenuating the high-frequency signal outputted from the first variable attenuator and outputting the high-frequency signal to an output terminal; and an output power detection circuit for monitoring output power of the high-frequency signal outputted from the second variable attenuator and outputting an output power detection signal.

Further, the output power stabilization circuit and the high output amplifier device using the same according to the present invention includes: a temperature monitoring circuit for monitoring a temperature of the output power detection circuit and outputting a temperature monitoring signal; a control circuit for outputting a first control signal for controlling an attenuation amount in the first variable attenuator, and a second control signal for controlling an attenuation amount in the second variable attenuator; and an attenuation amount setting circuit for inputting the first control signal and the output power detection signal, the attenuation amount setting circuit being for making comparison between the first control signal and the output power detection signal and outputting a first attenuation amount adjustment signal for adjusting the attenuation amount in the first variable attenuator.

The control circuit inputs the temperature monitoring signal and an output power setting signal for setting the output power of the high-frequency signal outputted from the output terminal to set power, the control circuit being for outputting the first control signal for controlling the attenuation amount in the first variable attenuator, and the second control signal for controlling the attenuation amount in the second variable attenuator, the first control signal and the second control signal having been obtained by referring to previously stored table data, based on the output power setting signal and the temperature monitoring signal which have been inputted to the control circuit.

The table data is configured by data for setting first attenuation amount setting data for setting the attenuation amount in the first variable attenuator and second attenuation amount setting data for setting the attenuation amount in the second variable attenuator, in correspondence to respective combinations of the output power detection signal and the temperature monitoring signal.

The second variable attenuator sets the attenuation amount to a set value, according to the second control signal, and the first variable attenuator changes the attenuation amount according to the first attenuation amount adjustment signal, so that the output power of the high-frequency signal outputted from the output terminal is converged to the set power.

### Advantageous Effects of Invention

According to the present invention, it is possible to maintain the output power of a high-frequency signal at a fixed value with high accuracy, against temperature changes, with a simple structure.

### BRIEF DESCRIPTION OF DRAWINGS

FIG. 1 is a functional block diagram illustrating a structure of an output power stabilization circuit according to a first embodiment of the present invention.

FIG. 2 is a circuit diagram illustrating a differential amplifier, illustrating an attenuation amount setting circuit in a case where a variable attenuator characteristic (a control voltage to an attenuation amount) has a negative slope, according to the first embodiment of the present invention.

FIG. 3 is a circuit diagram illustrating the differential amplifier, illustrating the attenuation amount setting circuit in a case where the variable attenuator characteristic (the control voltage to the attenuation amount) has a positive slope, according to the first embodiment of the present invention.

FIG. 4 is a flow chart illustrating operations of the output power stabilization circuit according to the first embodiment of the present invention.

FIG. 5 is a functional block diagram illustrating a structure of a high output amplifier device according to a second embodiment of the present invention.

FIG. 6 is a functional block diagram illustrating a modification of the high output amplifier device according to the second embodiment of the present invention.

FIG. 7 is a functional block diagram illustrating another modification of the high output amplifier device according to the second embodiment of the present invention.

FIG. 8 is a functional block diagram illustrating a structure of a high output amplifier device according to a third embodiment of the present invention.

FIG. 9 is a functional block diagram illustrating a structure of a high output amplifier device according to a fourth embodiment of the present invention.

FIG. 10 is a view illustrating timings of switching over of control terminals in a single-pole single-throw switch and a single-pole double-throw switch according to the fourth embodiment of the present invention.

### DESCRIPTION OF EMBODIMENTS

### First Embodiment

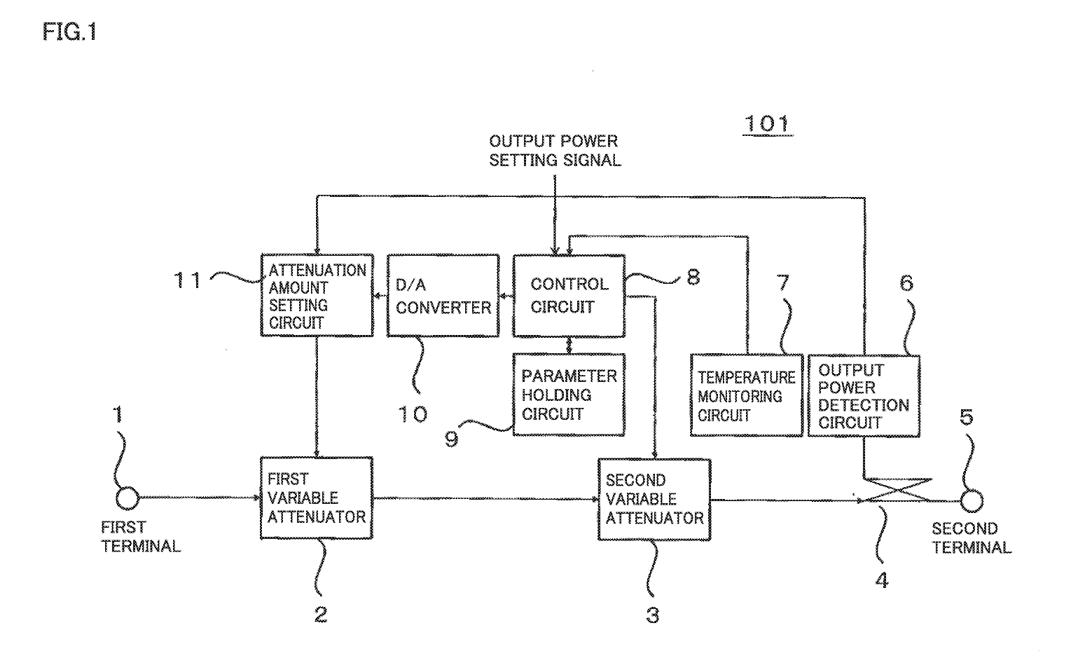

A first embodiment of the present invention will be described with reference to the drawings. FIG. 1 is a functional block diagram illustrating a structure of an output power stabilization circuit according to the first embodiment of the present invention. Referring to FIG. 1, an output power stabilization circuit 101 includes a first terminal 1, a first variable attenuator 2, a second variable attenuator 3, a coupler 4, a second terminal 5, an output power detection circuit 6, a temperature monitoring circuit 7, a control circuit 8, a parameter holding circuit 9, a D/A converter 10, and an attenuation amount setting circuit 11.

First variable attenuator 2 attenuates a high-frequency signal inputted thereto through first terminal 1 and outputs the signal. Second variable attenuator 3 attenuates the high-frequency signal outputted from first variable attenuator 2 and outputs the signal. Coupler 4 outputs the high-frequency signal outputted from second variable attenuator 3, to second terminal 5 that is an output terminal of output power stabilization circuit 101. Further, coupler 4 extracts a portion of the output power of the high-frequency signal outputted from second variable attenuator 3 and outputs the signal through a branch output.

Output power detection circuit 6 converts the power of the high-frequency signal outputted from the branch output of coupler 4 into an analog voltage signal and outputs the signal as an output power detection signal. In this way, output power detection circuit 6 monitors the output power of the high-frequency signal outputted from second terminal 5.

In other words, it can be said that output power detection circuit 6 monitors the output power of the high-frequency signal outputted from second variable attenuator 3.

Temperature monitoring circuit 7 is installed in output power detection circuit 6 or installed near output power detection circuit 6. Temperature monitoring circuit 7 monitors the temperature of output power detection circuit 6 and outputs a temperature monitoring signal. It can be said that temperature monitoring circuit 7 monitors the temperature of output power stabilization circuit 101 and outputs a temperature monitoring signal.

Parameter holding circuit 9 holds table data as held parameter values, wherein the table data is based on the combinations of temperatures of output power stabilization circuit 101 (temperature monitoring signals) and output power detection signals corresponding to output powers of high-frequency signals outputted from second terminal 5 in output power stabilization circuit 101, which have been previously obtained through measurements or simulations. For example, while the attenuation amount in first variable attenuator 2 is fixed, the attenuation amount in second variable attenuator 3 is set to be plural values to vary the output power outputted from second terminal 5, thereby providing respective output power detection signals corresponding to varied output powers outputted from second terminal 5. The table data was obtained by previously determining the temperature dependency of these output power detection signals, with respect to plural temperatures, through measurements or simulations.

That is, the table data sets first attenuation amount setting data for setting the attenuation amount in first variable attenuator 2 and second attenuation amount setting data for setting the attenuation amount in second variable attenuator 3, in correspondence to the combinations of respective output power detection signals and respective temperature monitoring signals, based on the temperature dependency of the output power detection signals with respect to plural temperatures.

The temperature monitoring signal outputted from temperature monitoring circuit 7 and an output power setting signal for setting set output power are inputted to control circuit 8, wherein the output power setting signal is inputted from the outside of output power stabilization circuit 101, and this set output power corresponds to the output power of the high-frequency signal outputted from second terminal 5 in output power stabilization circuit 101. Control circuit 8 outputs a first control signal, which is a digital signal, for controlling the attenuation amount in first variable attenuator 2, and a second control signal, which is a digital signal, for controlling the attenuation amount in second variable attenuator 3.

Control circuit 8 refers to the held parameter values which are the table data having been previously stored in parameter holding circuit 9, based on the output power setting signal and the temperature monitoring signal, wherein the table data is based on the combinations of temperatures of output power stabilization circuit 101 (temperature monitoring signals) and output power detection signals corresponding to the output powers of high-frequency signals outputted from second terminal 5 in output power stabilization circuit 101. Control circuit 8 outputs the first control signal and the second control signal which correspond to the held parameters obtained by referring to parameter holding circuit 9, wherein the first control signal and the second control signal make the output power of the high-frequency signal outputted from second terminal 5 in output power stabilization circuit 101 be the output power set by the output power setting signal.

The first control signal and the second control signal which are outputted from control circuit 8 are digital signals. D/A converter 10 converts the first control signal from the digital signal into an analog voltage signal. The first control signal having been converted into the analog voltage signal is inputted to attenuation amount setting circuit 11, together with the output power detection signal which is an analog voltage signal. The first control signal having been converted into the analog voltage signal can be said to be the target value of the output power detection signal which is the analog voltage signal.

The first control signal and the output power detection signal are inputted to the attenuation amount setting circuit 11. Attenuation amount setting circuit 11 makes comparison between the first control signal and the output power detection signal and outputs a first attenuation amount adjustment signal for adjusting the attenuation amount in first variable attenuator 2.

Second variable attenuator 3 inputs the second control signal and sets the attenuation amount therein to be the determined value, according to the second control signal.

First variable attenuator 2 inputs the first attenuation amount adjustment signal and changes the attenuation amount therein according to the first attenuation amount adjustment signal, thereby converging the output power of the high-frequency signal outputted from second terminal 5 in output power stabilization circuit 101 to the output power set by the output power setting signal.

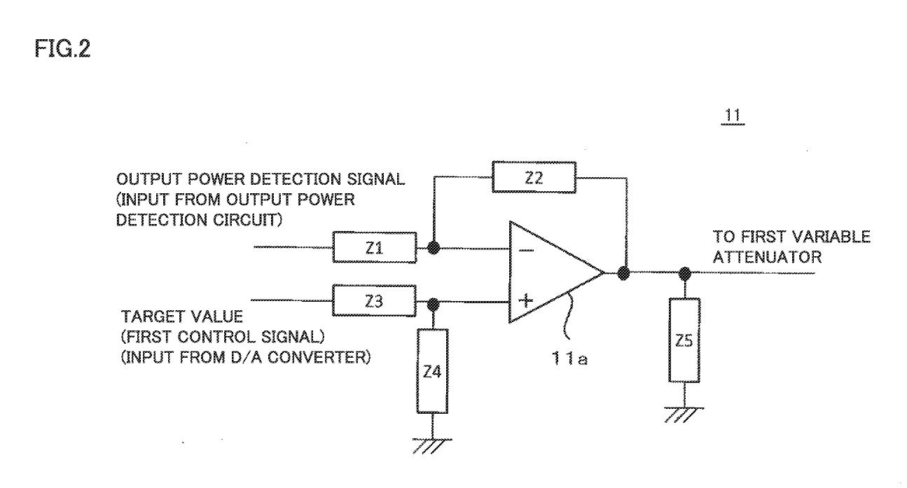

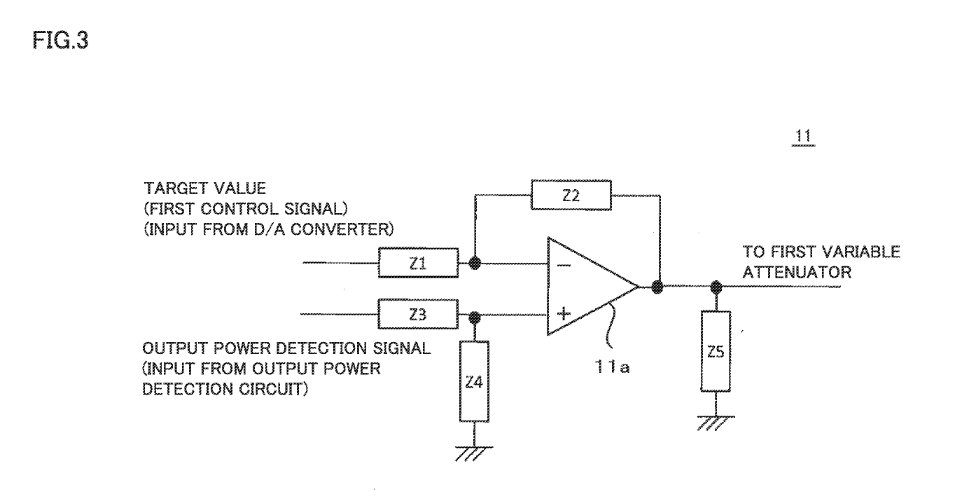

Attenuation amount setting circuit 11 is configured by a differential amplifier illustrated in FIGS. 2 and 3. FIG. 2 is a circuit diagram illustrating the differential amplifier, illustrating an attenuation amount setting circuit in a case where the variable attenuator characteristic (the control voltage to the attenuation amount) has a negative slope, according to the first embodiment of the present invention. FIG. 3 is a circuit diagram illustrating the differential amplifier, illustrating an attenuation amount setting circuit in a case where the variable attenuator characteristic (the control voltage to the attenuation amount) has a positive slope, according to the first embodiment of the present invention.

Referring to FIG. 2, in attenuation amount setting circuit 11, the output power detection signal is inputted to the inverting input terminal (the minus terminal) in a differential amplifier 11a, while the first control signal is inputted to the non-inverting input terminal (the plus terminal) in differential amplifier 11a. The output from differential amplifier 11a is outputted to first variable attenuator 2.

Referring to FIG. 3, in attenuation amount setting circuit 11, the first control signal is inputted to the inverting input terminal (the minus terminal) in differential amplifier 11a, while the output power detection signal is inputted to the non-inverting input terminal (the plus terminal) in differential amplifier 11a. The output from differential amplifier 11a is outputted to first variable attenuator 2.

Through the analog voltage signal, the attenuation amount in first variable attenuator 2 can be set. Through the parallel digital signal, the attenuation amount in second variable attenuator 3 can be set. In order to stably control the output power of the high-frequency signal outputted from second terminal 5 in output power stabilization circuit 101 to the value set by the output power setting signal, with respect to the temperature of output power stabilization circuit 101, the attenuation amounts in first variable attenuator 2 and second variable attenuator 3 are properly set.

Second variable attenuator 3 is controlled by control circuit 8. Control circuit 8 acquires a set value for second variable attenuator 3 from parameter holding circuit 9 and sends this set value as the parallel digital signal to second variable attenuator 3, such that second variable attenuator 3 has a previously set attenuation amount, according to the output power of the high-frequency signal outputted from second terminal 5 in output power stabilization circuit 101 which is set by the output power setting signal.

First variable attenuator 2 is controlled, using the output power detection signal, and using the result of processing by control circuit 8 on the temperature monitoring signal outputted from temperature monitoring circuit 7 installed in output power detection circuit 6, wherein this output power detection signal is obtained by extracting the output power corresponding to second terminal 5 in output power stabilization circuit 101 through coupler 4 and converting it into a voltage signal by output power detection circuit 6. The temperature monitoring signal outputted from temperature monitoring circuit 7 can be said to be a temperature monitoring signal regarding output power stabilization circuit 101.

The output voltage value, which is the output power detection signal from output power detection circuit 6, is previously measured, wherein the output power detection signal from output power detection circuit 6 is uniquely determined by the combination of the output power from second terminal 5 in output power stabilization circuit 101 and the temperature of output power stabilization circuit 101. Parameter holding circuit 9 holds this measured output voltage value as the output voltage table data.

Control circuit 8 acquires, from parameter holding circuit 9, the output voltage table data from output power detection circuit 6 which has the same value as the temperature monitoring signal obtained from temperature monitoring circuit 7 and also has the same output power value as the output power value of the output power setting signal inputted from the outside. Further, control circuit 8 outputs the acquired output voltage table data as the first control signal, which is a digital signal, to D/A converter 10.

The data of the first control signal is converted into an analog voltage by D/A converter 10, and the first control signal converted into this analog voltage is inputted, as the target value of the output power of the high-frequency signal outputted from output power stabilization circuit 101, to one of the differential input terminals in differential amplifier 11a which constitutes attenuation amount setting circuit 11. The output voltage outputted from output power detection circuit 6 is inputted to the other differential input terminal in differential amplifier 11a (FIGS. 2 and 3). Attenuation amount setting circuit 11 having the aforementioned structure forms a closed loop that operates to make the electric potential difference between the differential input terminals to be zero, so that the output power value of the high-frequency signal from output power stabilization circuit 101, which is outputted from second terminal 5, is equal to the power of the high-frequency signal which is set by the output power setting signal set from the outside.

The first embodiment will be described in more detail. The variable attenuator in the first embodiment is divided into two variable attenuators, which are first variable attenuator 2 and second variable attenuator 3. Accordingly, at first, it is possible to provide an effect of increasing the control converging speed of the closed loop, due to the parallel processing by the two variable attenuators. Secondly, in a high output amplifier device that forms a phase synchronization loop which will be described later in a third embodiment, it is possible to provide an effect of preventing power of a high-frequency signal inputted to a phase synchronization circuit from being lowered to such a level as to disable the phase synchronization loop from attaining synchronization.

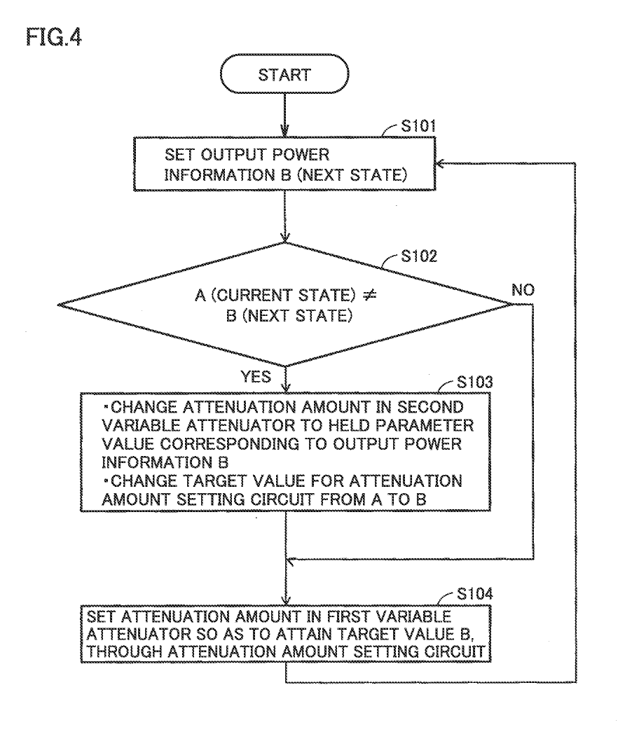

FIG. 4 is a flow chart illustrating operations of the output power stabilization circuit according to the first embodiment of the present invention.

Output power information of the output power setting signal having been set as a current state is defined as A, while output power information of the output power setting signal set as the next state is defined as B (step S101). If output power information A and output power information B are different from each other, the attenuation amount in second variable attenuator 3 is changed to a held parameter value corresponding to the output power information B and, further, the target value (the first control signal) for attenuation amount setting circuit 11 is changed from output power information A to output power information B (steps S102 and S103) Attenuation amount setting circuit 11 makes comparison between the target value B and the output voltage from output power detection circuit 6 and performs the closed-loop control such that the difference therebetween becomes zero, thereby setting the attenuation amount in first variable attenuator 2 and controlling the output power outputted from second terminal 5 in output power stabilization circuit 101 to the value of the output power B set as the next state (step S104).

As to setting of second variable attenuator 3 and setting of the target value in attenuation amount setting circuit 11 for first variable attenuator 2, the processes are executed in parallel, every time it has been determined that output power information A of the output power setting signal in the current state is different from output power information B of the output power setting signal for the next state. By setting the dynamic range of first variable attenuator 2 such that its performance changes due to the change thereof can be compensated, it is possible to prevent occurrences of instability in the closed-loop control and discontinuity in the attenuation amount setting data (the attenuation amount set values) for first variable attenuator 2, even if the output power stabilization circuit is influenced by external disturbances such as temperature changes.

More specifically, for example, when the power inputted to first terminal 1 is 0 dBm, and output power stabilization circuit 101 has a loss (including the temperature characteristics of second variable attenuator 3) of −5 to −10 dB within the operation temperature range (the usage temperature range), in a case where the set output power should be made to be −20 dBm, it is apparent that the sum of the attenuation amounts in first variable attenuator 2 and second variable attenuator 3 is required to be 10 to 15 dB. In this case, second variable attenuator 3 is set to have an attenuation amount of 9 dB, and the remaining attenuation amount, which is 1 to 6 dB, is controlled by first variable attenuator 2. At this time, the target value in attenuation amount setting circuit 11 for first variable attenuator 2 is set to be the value of the output voltage table data extracted from parameter holding circuit 9 by control circuit 8 and D/A converter 10 and, further, first variable attenuator 2 is set thereto by performing the closed-loop control according to the first attenuation amount adjustment signal outputted from attenuation amount setting circuit 11.

That is, when the output power has been set by the output power setting signal, the variation of the output power from second terminal 5 in output power stabilization circuit 101 due to temperature changes, within the variation range, is adjusted by adjusting, at any time, the attenuation amount in first variable attenuator 2 through the closed-loop control. For coping with the output power from second terminal 5 outside the temperature variation range, second variable attenuator 3 is set to have a fixed attenuation amount. Thus, even if temperature changes occur, the output power outputted from second terminal 5 in output power stabilization circuit 101 can be continuously and stably maintained at the output power set by the output power setting signal.

As described above, the attenuation amount in second variable attenuator 3 is roughly set, and the attenuation amount in first variable attenuator 2 is finely adjusted, in order to set the total attenuation amount. Accordingly, as compared with cases of converging the total attenuation amount with only a single variable attenuator, for example, first variable attenuator 2, which is analog-controlled, is allowed to have a narrower dynamic range than the dynamic range of only a single variable attenuator. This can shorten the time required for converging the total attenuation amount to a predetermined attenuation amount, as compared with cases of setting the total attenuation amount with only a single variable attenuator. That is, it is possible to shorten the time required for converging the attenuation amount through the closed-loop control.

Second variable attenuator 3 is controlled in parallel through the digital signal, which enables immediate setting of the attenuation amount therein without converting the setting information from control circuit 8 into an analog voltage, thereby shortening the setting processing time.

In the output power stabilization circuit according to the first embodiment, the variable attenuator is divided into the two variable attenuators, which are first variable attenuator 2 and second variable attenuator 3. This can provide the effect of increasing the control converging speed of the closed-loop control, due to the parallel processing by the two variable attenuators, as described above.

### Second Embodiment

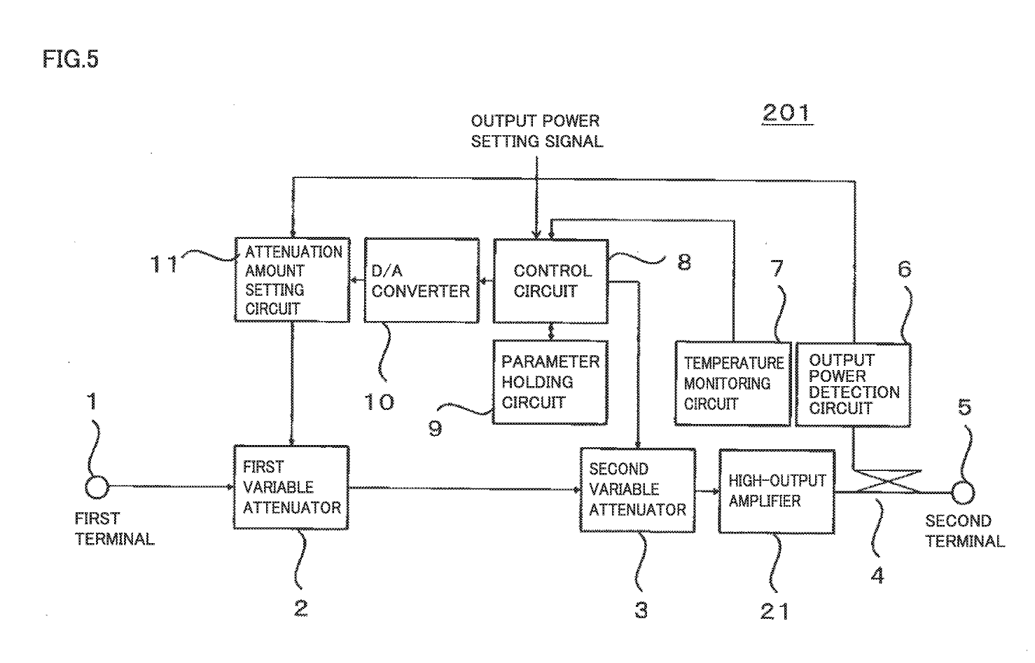

A second embodiment of the present invention will be described with reference to the drawings. FIG. 5 is a functional block diagram illustrating a structure of a high output amplifier device according to the second embodiment of the present invention. In FIG. 5, the same or similar components as or to those in FIG. 1 will be designated by the same reference characters and will not be described redundantly.

In the second embodiment, there is provided a high output amplifier device 201 provided with a high-output amplifier 21, between a second variable attenuator 3 and a coupler 4 in an output power stabilization circuit 101 according to the first embodiment. Referring to FIG. 5, a first variable attenuator 2 attenuates a high-frequency signal inputted thereto through a first terminal 1 and outputs the signal. Second variable attenuator 3 attenuates the high-frequency signal outputted from first variable attenuator 2 and outputs the signal to high-output amplifier 21. High-output amplifier 21 amplifies the high-frequency signal outputted from second variable attenuator 3 and outputs the amplified high-frequency signal to coupler 4. Coupler 4 outputs the high-frequency signal outputted from high-output amplifier 21 to a second terminal 5 that is an output terminal. Further, coupler 4 extracts a portion of the output power of the high-frequency signal outputted from high-output amplifier 21 and outputs it through a branch output.

An output power detection circuit 6 converts the power of the high-frequency signal outputted from the branch output of coupler 4 into an analog voltage signal and outputs the signal as an output power detection signal. In this way, output power detection circuit 6 monitors the output power of the high-frequency signal outputted from second terminal 5.

In other words, it can be said that output power detection circuit 6 monitors the output power of the high-frequency signal outputted from high-output amplifier 21.

A temperature monitoring circuit 7 is installed in output power detection circuit 6 or installed near output power detection circuit 6. Temperature monitoring circuit 7 monitors the temperature of output power detection circuit 6 and outputs a temperature monitoring signal. It can be said that temperature monitoring circuit 7 monitors the temperature of high output amplifier device 201 and outputs a temperature monitoring signal.

A parameter holding circuit 9 holds table data as held parameter values, wherein the table data is based on the combinations of temperatures of the high output amplifier device 201 (temperature monitoring signals) and output power detection signals corresponding to output powers of high-frequency signals outputted from second terminal 5 in high output amplifier device 201, which were previously obtained through measurements or simulations. For example, while the attenuation amount in first variable attenuator 2 is fixed, the attenuation amount in second variable attenuator 3 is set to be plural values to vary the output power outputted from second terminal, thereby providing respective output power detection signals corresponding to varied output powers outputted from the second terminal. The table data is obtained by previously determining the temperature dependency of the output power detection signals, with respect to plural temperatures, through measurements or simulations.

That is, the table data sets first attenuation amount setting data for setting the attenuation amount in first variable attenuator 2 and second attenuation amount setting data for setting the attenuation amount in second variable attenuator 3, in correspondence to the combinations of respective output power detection signals and respective temperature monitoring signals, based on the temperature dependency of the output power detection signals with respect to plural temperatures.

The temperature monitoring signal outputted from temperature monitoring circuit 7 and an output power setting signal for setting set output power are inputted to control circuit 8, wherein the output power setting signal is inputted from the outside of high output amplifier device 201, and this set output power corresponds to the output power of the high-frequency signal outputted from second terminal 5 in high output amplifier device 201. Control circuit 8 outputs a first control signal, which is a digital signal, for controlling the attenuation amount in first variable attenuator 2, and a second control signal, which is a digital signal, for controlling the attenuation amount in second variable attenuator 3.

In response to the output power setting signal, control circuit 8 refers to the held parameter values which are the table data having been previously stored in parameter holding circuit 9, based on the output power setting signal and the temperature monitoring signal, wherein the table data is based on the combinations of temperatures of high output amplifier device 201 (temperature monitoring signals) and output power detection signals corresponding to the output powers of high-frequency signals outputted from second terminal 5 in high output amplifier device 201. Control circuit 8 outputs the first control signal and the second control signal which correspond to the held parameters obtained by referring to parameter holding circuit 9, wherein the first control signal and the second control signal make the output power of the high-frequency signal outputted from second terminal 5 in high output amplifier device 201 be the output power set by the output power setting signal.

The first control signal and the second control signal which are outputted from control circuit 8 are digital signals. D/A converter 10 converts the first control signal from the digital signal into an analog voltage signal. The first control signal having been converted into the analog voltage signal is inputted to attenuation amount setting circuit 11, together with the output power detection signal which is an analog voltage signal. The first control signal having been converted into the analog voltage signal can be said to be the target value of the output power detection signal which is the analog voltage signal.

The first control signal and the output power detection signal are inputted to attenuation amount setting circuit 11. Attenuation amount setting circuit 11 makes comparison between the first control signal and the output power detection signal and outputs a first attenuation amount adjustment signal for adjusting the attenuation amount in first variable attenuator 2.

Second variable attenuator 3 inputs the second control signal and sets the attenuation amount therein to be the determined value, according to the second control signal.

First variable attenuator 2 inputs the first attenuation amount adjustment signal and changes the attenuation amount therein according to the first attenuation amount adjustment signal, thereby converging the output power of the high-frequency signal outputted from the high output amplifier device 201 to the output power set by the output power setting signal.

Attenuation amount setting circuit 11 is configured by the differential amplifier illustrated in FIGS. 2 and 3. FIG. 2 is the differential amplifier that represents the attenuation amount setting circuit according to the first embodiment of the present invention, but is also applied to the second embodiment.

Referring to FIG. 2, in attenuation amount setting circuit 11, the output power detection signal is inputted to the inverting input terminal (the minus terminal) in differential amplifier 11a, while the first control signal is inputted to the non-inverting input terminal (the plus terminal) in differential amplifier 11a. The output from differential amplifier 11a is outputted to first variable attenuator 2.

Referring to FIG. 3, in attenuation amount setting circuit 11, the first control signal is inputted to the inverting input terminal (the minus terminal) in differential amplifier 11a, while the output power detection signal is inputted to the non-inverting input terminal (the plus terminal) in differential amplifier 11a. The output from differential amplifier 11a is outputted to first variable attenuator 2.

Through the analog voltage signal, the attenuation amount in first variable attenuator 2 can be set. Through the parallel digital signal, the attenuation amount in second variable attenuator 3 can be set. In order to stably control the high-frequency power outputted from high output amplifier device 201 to the value set by the output power setting signal, with respect to the temperature of high output amplifier device 201, the attenuation amounts in first variable attenuator 2 and second variable attenuator 3 are properly set.

Second variable attenuator 3 is controlled by control circuit 8. Control circuit 8 acquires a set value for second variable attenuator 3 from parameter holding circuit 9 and sends this set value as the parallel digital signal to second variable attenuator 3, such that second variable attenuator 3 has a previously set attenuation amount, according to the output power of the high-frequency signal outputted from high output amplifier device 201 which is set by the output power setting signal.

First variable attenuator 2 is controlled through processing by control circuit 8 on the output power detection signal obtained from output power detection circuit 6 and the temperature monitoring signal outputted from temperature monitoring circuit 7 installed in output power detection circuit 6, wherein the output power detection signal is obtained by extracting the output from second terminal 5 in high-output amplifier 21 through coupler 4. The temperature monitoring signal outputted from temperature monitoring circuit 7 can be said to be a temperature monitoring signal regarding high output amplifier device 201.

The output voltage value, which is the output power detection signal from output power detection circuit 6, is previously measured, wherein the output power detection signal from output power detection circuit 6 is uniquely determined by the combination of the output power from high-output amplifier 21 and the temperature of high-output amplifier 21. Parameter holding circuit 9 holds this measured output voltage value as the output voltage table data.

Control circuit 8 acquires, from parameter holding circuit 9, the output voltage table data from output power detection circuit 6 which has the same value as the temperature monitoring signal obtained from temperature monitoring circuit 7 and also has the same output power value as the output power value of the output power setting signal inputted from the outside. Further, control circuit 8 outputs the acquired output voltage table data as the first control signal, which is a digital signal, to D/A converter 10.

The data of the first control signal is converted into an analog voltage by D/A converter 10, and the first control signal converted into the analog voltage is inputted, as the target value of the output power of the high-frequency signal outputted from output power stabilization circuit 101, to one of the differential input terminals in differential amplifier 11a which constitutes attenuation amount setting circuit 11. The output voltage outputted from output power detection circuit 6 is inputted to the other differential input terminal in differential amplifier 11a (FIGS. 2 and 3). Attenuation amount setting circuit 11 having the aforementioned structure forms a closed loop that operates to make the electric potential difference between the differential input terminals to be zero, so that the output power value of the high-frequency signal from high output amplifier device 201, which is outputted from second terminal 5, is equal to the power of the high-frequency signal which is set by the output power setting signal set from the outside.

The high output amplifier device according to the second embodiment of the present invention performs the same operations as those of the flow chart illustrated in FIG. 4. FIG. 4 is a flow chart illustrating operations of the output power stabilization circuit according to the first embodiment of the present invention, but is also applied to the high output amplifier device according to the second embodiment.

Output power information of the output power setting signal having been set as a current state is defined as A, while output power information of the output power setting signal set as the next state is defined as B (step S101).

If output power information A and output power information B are different from each other, the attenuation amount in second variable attenuator 3 is changed to a held parameter value corresponding to output power information B and, further, the target value (the first control signal) for attenuation amount setting circuit 11 is changed from output power information A to output power information B (steps S102 and S103).

Attenuation amount setting circuit 11 makes comparison between the target value B and the output voltage from output power detection circuit 6 and performs the closed-loop control such that the difference therebetween becomes zero, thereby setting the attenuation amount in first variable attenuator 2 and controlling the output power outputted from second terminal 5 in high output amplifier device 201 to the value of the output power B set as the next state (step S104).

As to setting of second variable attenuator 3 and setting of the target value in attenuation amount setting circuit 11 for first variable attenuator 2, the processes are executed in parallel, every time it has been determined that output power information A of the output power setting signal in the current state is different from output power information B of the output power setting signal for the next state. By setting the dynamic range of first variable attenuator 2 such that its performance changes due to changes thereof can be compensated, it is possible to prevent occurrences of instability in the closed-loop control and discontinuity in the attenuation amount setting data (the attenuation amount set values) for first variable attenuator 2, even if the high output amplifier device is influenced by external disturbances such as temperature changes.

More specifically, for example, it is assumed that the power inputted to first terminal 1 is 0 dBm, and high output amplifier device 201 has a gain (including the temperature characteristics of the second variable attenuator 3) of 46 to 50 dB within the operation temperature range (the usage temperature range). In this case, when the set output power from second terminal 5 in high output amplifier device 201 should be made to be 40 dBm, it is apparent that the sum of the attenuation amounts in first variable attenuator 2 and second variable attenuator 3 is required to be 6 to 10 dB. In this case, second variable attenuator 3 is set to have an attenuation amount of 5 dB, and the remaining attenuation amount, which is 1 to 5 dB, is controlled by first variable attenuator 2. At this time, the target value in attenuation amount setting circuit 11 for first variable attenuator 2 is set to be the value of the output voltage table data extracted from parameter holding circuit 9 by control circuit 8 and D/A converter 10 and, further, first variable attenuator 2 is set thereto by performing the closed-loop control according to the first attenuation amount adjustment signal outputted from attenuation amount setting circuit 11.

When the set output power from second terminal 5 in high output amplifier device 201 is changed from 40 dBm to 30 dBm, second variable attenuator 3 is set to have an attenuation amount of 15 dB, and the remaining attenuation amount, which is 1 to 5 dB, is controlled by first variable attenuator 2. At this time, the target value in attenuation amount setting circuit 11 for first variable attenuator 2 is set to be the value of the output voltage table data extracted from parameter holding circuit 9 by control circuit 8 and D/A converter 10 and, further, first variable attenuator 2 is controlled thereto through the closed loop with the output from attenuation amount setting circuit 11. By previously determining the attenuation amount in second variable attenuator 3, in such a way as to fix the dynamic range of first variable attenuator 2, as described above, it is possible to control the output power from second terminal 5 in high output amplifier device 201 to a fixed value.

That is, when the output power has been set by the output power setting signal, the variation of the output power from second terminal 5 in high output amplifier device 201 due to temperature changes, within the variation range, is adjusted by adjusting, at any time, the attenuation amount in first variable attenuator 2 through the closed-loop control. For coping with the output power from second terminal 5 outside the temperature variation range, second variable attenuator 3 sets the output power to have a fixed attenuation amount. Thus, even if temperature changes occur, the output power from second terminal 5 in high output amplifier device 201 can be continuously and stably maintained at the output power set by the output power setting signal.

As described above, the attenuation amount in second variable attenuator 3 is roughly set, and the attenuation amount in first variable attenuator 2 is finely adjusted, in order to set the total attenuation amount. Accordingly, as compared with cases of converging the total attenuation amount with only a single variable attenuator, for example, first variable attenuator 2, which is analog-controlled, is allowed to have a narrower dynamic range than the dynamic range of only a single variable attenuator. This can shorten the time required for converging the total attenuation amount to a predetermined attenuation amount, as compared with cases of setting the total attenuation amount with only a single variable attenuator. That is, it is possible to shorten the time required for converging the attenuation amount through the closed-loop control.

Second variable attenuator 3 is controlled in parallel through the digital signal, which enables immediate setting of the attenuation amount therein without converting the setting information from control circuit 8 into an analog voltage, thereby shortening the setting processing time.

In the high output amplifier device according to the second embodiment, the variable attenuator is divided into the two variable attenuators, which are first variable attenuator 2 and second variable attenuator 3. This can provide the effect of increasing the control converging speed of the closed-loop control, due to the parallel processing by the two variable attenuators, as described above.

Since setting of second variable attenuator 3 is performed for each desired output power information set by the output power setting signal, it is possible to limit the setting range of first variable attenuator 2. This is also advantageous in preventing a non-linear region of first variable attenuator 2 from being utilized, in a case where first variable attenuator 2 has a non-linear region in its attenuation characteristic.

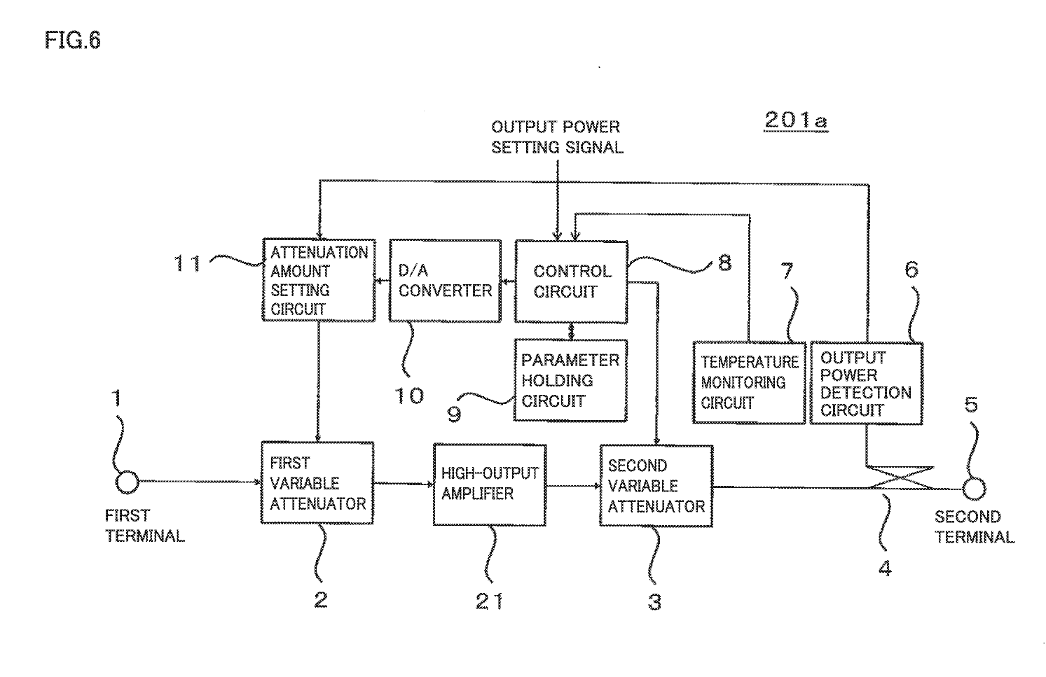

As a modification of the second embodiment, as illustrated in FIG. 6, high-output amplifier 21 can be also arranged between first variable attenuator 2 and second variable attenuator 3.

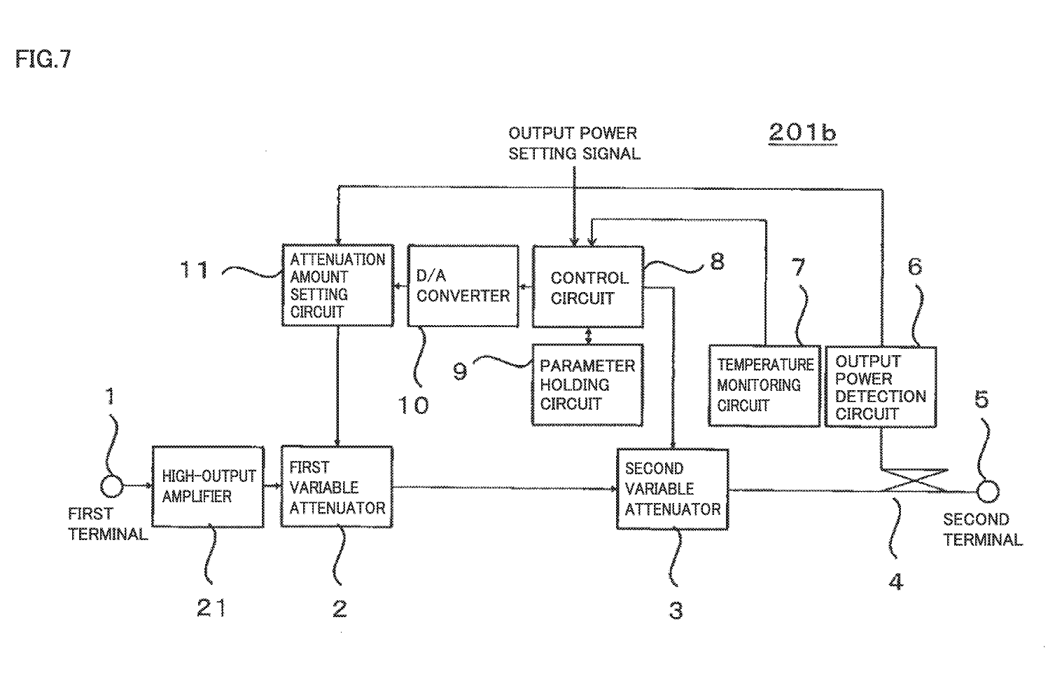

Further, as a modification of the second embodiment, as illustrated in FIG. 7, high-output amplifier 21 can be also arranged between the first terminal and first variable attenuator 2.

### Third Embodiment

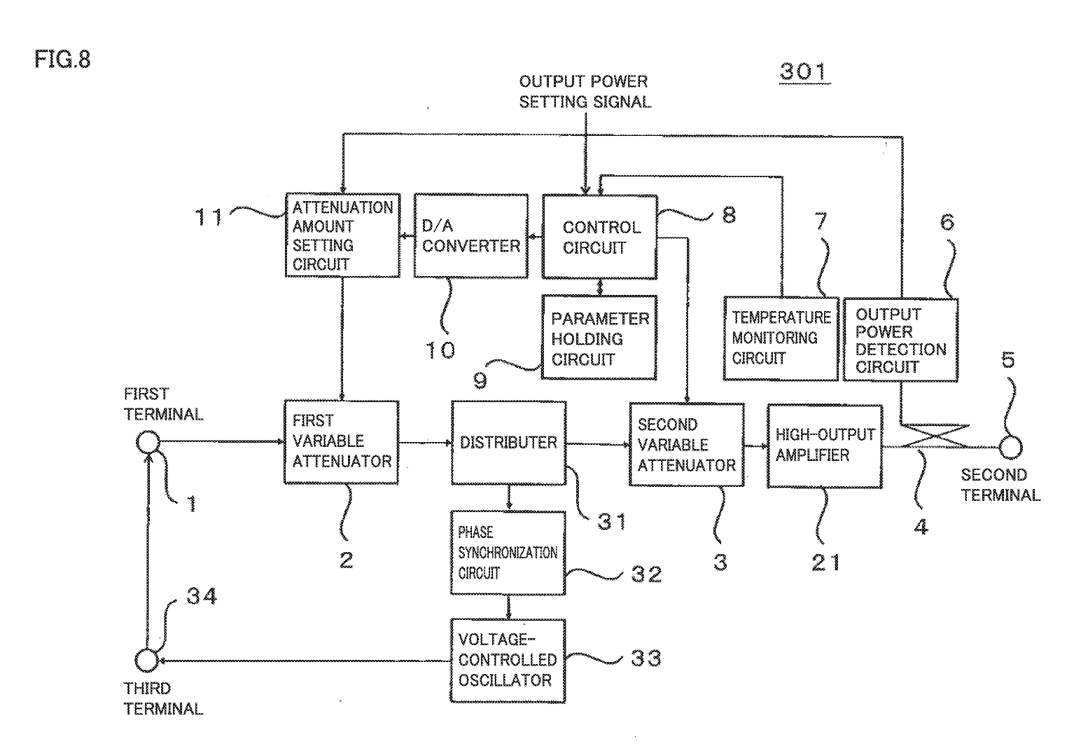

A high output amplifier device according to a third embodiment of the present invention will be described with reference to the drawings. FIG. 8 is a functional block diagram illustrating a structure of a high-output amplifier device according to the third embodiment of the present invention. In FIG. 8, the same or similar components as or to those of FIGS. 1 and 5 will be designated by the same reference characters and will not be described redundantly.

According to the third embodiment, there is provided a high-output amplification device 301 provided with a distributor 31 for distributing a high-frequency signal outputted from a first variable attenuator 2, between first variable attenuator 2 and a second variable attenuator in a high output amplifier device 201 according to the second embodiment. A main-signal output from distributor 31 is inputted to second variable attenuator 3. A distributed output from distributor 31 is inputted to a phase synchronization circuit 32. The output from phase synchronization circuit 32 is inputted to a voltage-controlled oscillator 33. Voltage-controlled oscillator 33 generates a high-frequency signal and outputs the signal to a third output terminal 34. Third output terminal 34 and a first terminal 1 are connected to each other, so that distributor 31, phase synchronization circuit 32, and voltage-controlled oscillator 33 form a phase synchronization loop.

In the first and second embodiments, the high-frequency signal inputted to first terminal 1 from the outside is set to have predetermined output power and, then, the signal is outputted from second terminal 5. However, with high output amplifier device 301 according to the third embodiment, it is possible to generate a high-frequency signal with a stabilized frequency, without necessitating a high-frequency signal from the outside. The other structures, operations and effects are the same as those of high output amplifier device 201 according to the second embodiment.

### Fourth Embodiment

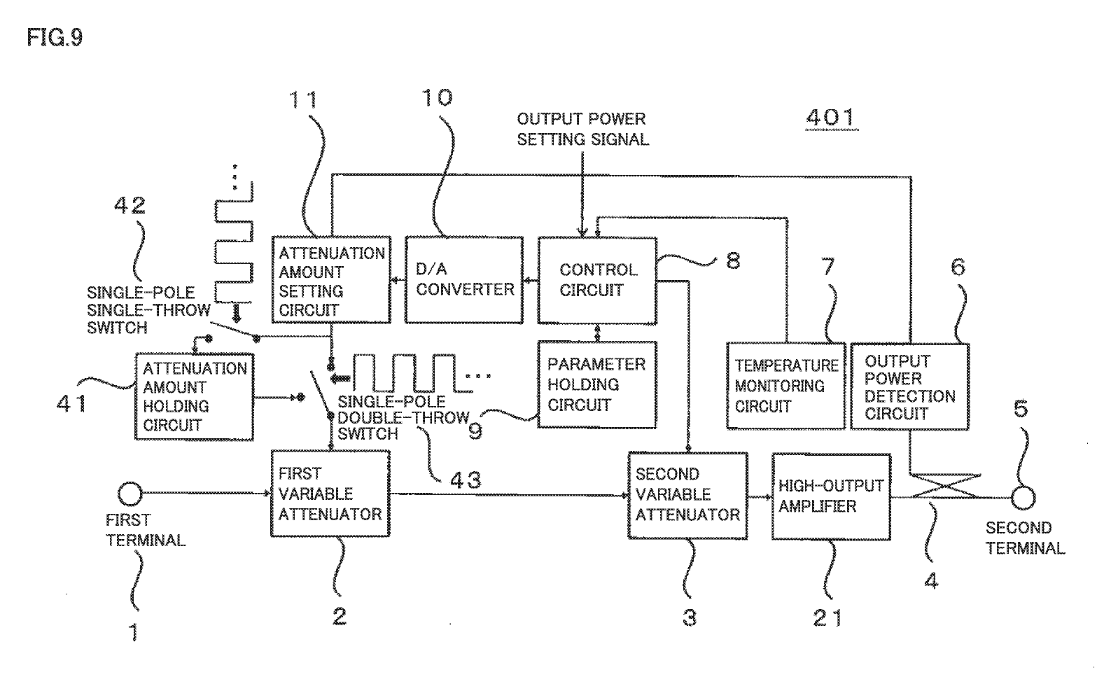

A high output amplifier device according to a fourth embodiment of the present invention will be described with reference to the drawings. FIG. 9 is a functional block diagram illustrating a structure of a high output amplifier device according to the fourth embodiment of the present invention. In FIG. 9, the same components as or to those of FIGS. 1 and 5 will be designated by the same reference characters and will not be described redundantly.

A high output amplifier device 401 according to the fourth embodiment includes an attenuation amount holding circuit 41, a single-pole single-throw switch 42, and a single-pole double-throw switch 43, between an attenuation amount setting circuit 11 and a first variable attenuator 2 in a high output amplifier device 201 according to the second embodiment. Single-pole single-throw switch 42 is provided between attenuation amount setting circuit 11 and an attenuation amount holding circuit 41. That is, single-pole single-throw switch 42 has one end connected to the output of attenuation amount setting circuit 11 and another end connected to the input of attenuation amount holding circuit 41. Single-pole double-throw switch 43 has a common terminal connected to first variable attenuator 2, a first switching terminal connected to the output of attenuation amount setting circuit 11, and a second switching terminal connected to the output of attenuation amount holding circuit 41.

Attenuation amount holding circuit 41 has a function of holding the same voltage as the output voltage from attenuation amount setting circuit 11, only within a period in which single-pole single-throw switch 42 is ON, unless the output voltage outputted from an output power detection circuit 6 has a minimum value (the pulse power is ineffective). When the pulse power is ineffective, attenuation amount holding circuit 41 has a function of maintaining the same voltage as the output voltage from the attenuation amount setting circuit 11 just before the pulse power becomes ineffective. In this case, the description “the pulse power is ineffective” means that the pulse power has a power value of zero. On the contrary, the description “the pulse power is effective” means that the pulse power has a power value of not zero.

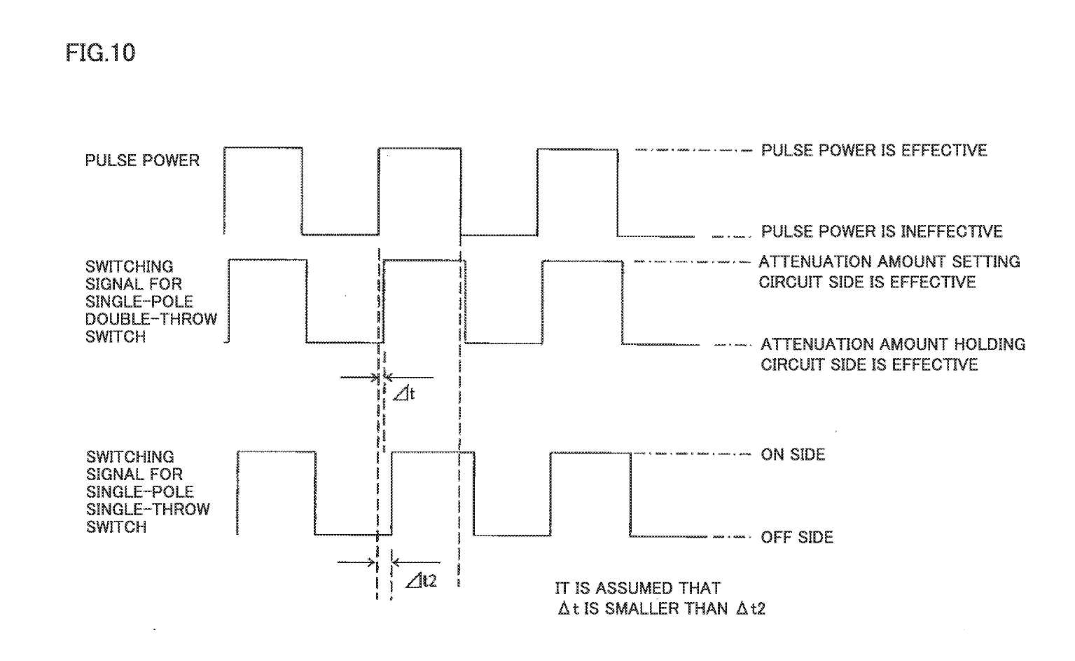

The switching of the control terminals of single-pole single-throw switch 42 and single-pole double-throw switch 43 is controlled by timing signals that are delayed (offset-delayed) by arbitrary times (a first time: Δt, a second time: Δt2, wherein Δt<Δt2) from pulse power timing, as illustrated in FIG. 10.

Within a most part of the period in which the pulse power is effective (a period in which the pulse power is stably effective), single-pole double-throw switch 43 is being switched to the output side of attenuation amount setting circuit 11, while single-pole single-throw switch 42 is brought into an ON state. If the pulse power is changed from being effective to being ineffective, at first, single-pole double-throw switch 43 is switched over from the output side of attenuation amount setting circuit 11 to the output side of attenuation amount holding circuit 41. Thereafter, single-pole single-throw switch 42 is brought into an OFF state, and single-pole double-throw switch 43 and single-pole single-throw switch 42 are stabilized.

If the pulse power is changed from being ineffective to being effective, at first, single-pole double-throw switch 43 is switched over from the output side of attenuation amount holding circuit 41 to the output side of attenuation amount setting circuit 11, after the elapse of time Δt since the change of the pulse power from being ineffective to being effective. Then, after the elapse of time Δt2 since the change of the pulse power from being ineffective to being effective, single-pole single-throw switch 42 is brought into an ON state, and single-pole double-throw switch 43 and single-pole single-throw switch 42 are stabilized.

Since these timings are offset, when the pulse power is effective, output power detection circuit 6 is caused to detect the output power of the pulse power, in the state where the output of attenuation amount holding circuit 41 is effective. Further, from the state where the output power has been controlled to output power close to that at the time of closed-loop control operations, single-pole double-throw switch 43 is switched over to the output side of attenuation amount setting circuit 11, thereby making the closed-loop control be effective. This can minimize the time required for stabilizing the output power from high output amplifier device 401.

Immediately after the pulse power has become effective, the single-pole double-throw switch 43 has been switched over to the output side of attenuation amount holding circuit 41. Therefore, immediately after the closed-loop operation has been established, attenuation amount holding circuit 41 can be operated. When the pulse power is ineffective, attenuation amount holding circuit 41 does not update the voltage held therein and, therefore, holds the voltage of the latest first attenuation amount adjustment signal during the closed-loop operation. The value of this voltage is applied as an initial value to first variable attenuator 2, at first, when the pulse power is effective.

With high output amplifier device 401 according to the second embodiment, when the pulse power is controlled, the closed-loop control for determining the attenuation amount in first variable attenuator 2 is operated in such a direction as to increase the output power from a second terminal 5 in high output amplifier device 401 to the target power value, during the time in which the pulse power becomes zero. Therefore, while the output power from second terminal 5 in high output amplifier device 401 is not converged to the target value, the control is performed in such a direction as to minimize the attenuation amount in first variable attenuator 2, so that the attenuation amount in first variable attenuator 2 is minimized.

If the pulse power is inputted again, the closed-loop control is operated, thereby setting the attenuation amount in first variable attenuator 2 such that the output power from second terminal 5 in high output amplifier device 401 becomes desired output power. There is a need for a time for converging the closed-loop control until the output power from second terminal 5 in high output amplifier device 401 is stabilized. Therefore, during the pulse power control, there is a need a time for stabilizing the output power from second terminal 5 in high output amplifier device 401 for every pulse. Furthermore, there is a need for a longest time required for converging the closed-loop control from the state where first variable attenuator 2 has been controlled to have a minimum attenuation amount therein.

However, with high output amplifier device 401 according to the fourth embodiment, if the pulse power becomes zero, single-pole single-throw switch 42 is turned off, and single-pole double-throw switch 43 is switched over to the side for making attenuation amount holding circuit 41 to be effective, thereby holding the attenuation amount set in first variable attenuator 2. Further, if the pulse power becomes effective, single-pole single-throw switch 42 is turned on, and single-pole double-throw switch 43 is switched over to the side for making attenuation amount setting circuit 11 to be effective. In this way, it possible to minimize the time required for converging the closed-loop control.

The other structures, operations and effects are the same as those of high output amplifier device 201 according to the second embodiment.

The present invention is not limited to those described in the aforementioned embodiments, as a matter of course. That is, in the present invention, various changes can be made to the aforementioned embodiments. For example, in the present invention, the phase synchronization loop configured by distributor 31, phase synchronization circuit 32, voltage-controlled oscillator 33, and third output terminal 34, which have been described in the third embodiment, can be also combined with the first embodiment, the modifications of the second embodiment, and the fourth embodiment. Further, in the present invention, attenuation amount holding circuit 41, single-pole single-throw switch 42 and single-pole double-throw switch 43, which have been described in the fourth embodiment, can be also combined with the first embodiment, the modification examples of the second embodiment, and the third embodiment.

### REFERENCE SIGNS LIST

1: First terminal (input terminal), 2: First variable attenuator, 3: Second variable attenuator, 4: Coupler, 5: Second terminal (output terminal), 6: Output power detection circuit, 7: Temperature monitoring circuit, 8: Control circuit, 9: Parameter holding circuit, 10: D/A converter, 11: Attenuation amount setting circuit, 11a: Differential amplifier, 21: High-output amplifier, 31: Distributor, 32: Phase synchronization circuit, 33: Voltage-controlled oscillator, 34: Third output terminal, 41: Attenuation amount holding circuit, 42: Single-pole single-throw switch, 43: Single-pole double-throw switch, 101: Output power stabilization circuit, 201: High output amplifier device, 201a: High output amplifier device, 201b: High output amplifier device, 301: High output amplifier device, 401: High output amplifier device

1. An output power stabilization circuit comprising:
a first variable attenuator for attenuating a high-frequency signal inputted to an input terminal;
a second variable attenuator for attenuating the high-frequency signal outputted from the first variable attenuator and outputting the high-frequency signal to an output terminal;
an output power detection circuit for monitoring output power of the high-frequency signal outputted from the second variable attenuator and outputting an output power detection signal;
a temperature monitoring circuit for monitoring a temperature of the output power detection circuit and outputting a temperature monitoring signal;
a control circuit for inputting the temperature monitoring signal and an output power setting signal for setting the output power of the high-frequency signal outputted from the output terminal to set power, the control circuit being for outputting a first control signal for controlling an attenuation amount in the first variable attenuator, and a second control signal for controlling an attenuation amount in the second variable attenuator, the first control signal and the second control signal having been obtained by referring to previously stored table data, based on the output power setting signal and the temperature monitoring signal which have been inputted to the control circuit; and
an attenuation amount setting circuit for inputting the first control signal and the output power detection signal, the attenuation amount setting circuit being for making comparison between the first control signal and the output power detection signal and outputting a first attenuation amount adjustment signal for adjusting the attenuation amount in the first variable attenuator,
wherein the control circuit refers to the table data adapted to set first attenuation amount setting data for setting the attenuation amount in the first variable attenuator and second attenuation amount setting data for setting the attenuation amount in the second variable attenuator, in correspondence to respective combinations of the output power detection signal and the temperature monitoring signal,
the second variable attenuator sets the attenuation amount to a set value, according to the second control signal,
the first variable attenuator changes the attenuation amount according to the first attenuation amount adjustment signal,
so that the output power of the high-frequency signal outputted from the output terminal is converged to the set power.

2. The output power stabilization circuit according to claim 1, wherein
the control circuit outputs, as the second control signal, an attenuation amount obtained by subtracting, from a total attenuation amount, a variation of an attenuation amount for correcting temperature dependency of a gain or loss between the input terminal and the output terminal, out of the total attenuation amount being a sum of the attenuation amount in the first variable attenuator and the attenuation amount in the second variable attenuator, and
the control circuit outputs, as the first control signal, a value of the output power detection signal that is stored as the first attenuation amount setting data in the table data, in correspondence to the temperature monitoring signal and the set power.

3. The output power stabilization circuit according to claim 1, wherein
the attenuation amount setting circuit includes a differential amplifier for differential inputting the first control signal having been converted into an analog voltage value, and the output power detection signal being an analog voltage value, and
the control circuit controls the first control signal such that a voltage between differential input terminals of the differential amplifier becomes zero.

4. The output power stabilization circuit according to claim 1, comprising:
a distributor provided between the first variable attenuator and the second variable attenuator;
a phase synchronization circuit for differential inputting an output signal distributed out of a high-frequency signal inputted to the distributor and for outputting the distributed output signal as a voltage; and
a voltage-controlled oscillator for generating and outputting a high-frequency signal based on the voltage outputted from the phase synchronization circuit and outputting the high-frequency signal to the first variable attenuator.

5. The output power stabilization circuit according to claim 1, comprising
an attenuation amount holding circuit;
a single-pole single-throw switch having one end connected to an output of the attenuation amount setting circuit and another end connected to an input of the attenuation amount holding circuit; and
a single-pole double-throw switch having a common terminal connected to the first variable attenuator, a first switching terminal connected to an output of the attenuation amount setting circuit and a second switching terminal connected to an output of the attenuation amount holding circuit,
wherein the inputted high-frequency signal is a pulse signal in which a period having high-frequency power and a period having no high-frequency power are alternately repeated,
in the period having no high-frequency power, the single-pole single-throw switch is in an OFF state, while the single-pole double-throw switch is switched over to the second switching terminal, and
in the period having high-frequency power, the single-pole single-throw switch is in an ON state, while the single-pole double-throw switch is switched over to the first switching terminal.

6. The output power stabilization circuit according to claim 5, wherein
when the period having no high-frequency power changes to the period having high-frequency power, the single-pole double-throw switch is switched over from the second switching terminal to the first switching terminal, after elapse of a first time since the change from the period having no high-frequency power to the period having high-frequency power, and
the single-pole single-throw switch is brought into an ON state from the OFF state, after elapse of a second time that is longer than the first time, since the change from the period having no high-frequency power to the period having high-frequency power.

7. A high output amplifier device comprising:
the output power stabilization circuit according to claim 1; and
a high-output amplifier for amplifying a high-frequency signal outputted from the second variable attenuator and outputting the amplified high-frequency signal to the output terminal, between the second variable attenuator and the output terminal;
wherein the output power detection circuit monitors output power of the high-frequency signal outputted from the high-output amplifier and outputs the output power detection signal.

8. A high output amplifier device comprising:
the output power stabilization circuit according to claim 1; and
a high-output amplifier for amplifying a high-frequency signal outputted from the first variable attenuator and outputting the amplified high-frequency signal to the second variable attenuator, between the first variable attenuator and the second variable attenuator.

9. A high output amplifier device comprising:
the output power stabilization circuit according to claim 1; and
a high-output amplifier for amplifying a high-frequency signal inputted from the input terminal and outputting the amplified high-frequency signal to the first variable attenuator, between the input terminal and the first variable attenuator.

10. A high output amplifier device comprising:
the output power stabilization circuit according to claim 6; and
a high-output amplifier for amplifying a high-frequency signal outputted from the second variable attenuator and outputting the amplified high-frequency signal to the output terminal, between the second variable attenuator and the output terminal;
wherein the output power detection circuit monitors output power of the high-frequency signal outputted from the high-output amplifier and outputs the output power detection signal.

11. A high output amplifier device comprising:
the output power stabilization circuit according to claim 6; and
a high-output amplifier for amplifying a high-frequency signal outputted from the first variable attenuator and outputting the amplified high-frequency signal to the second variable attenuator, between the first variable attenuator and the second variable attenuator.

12. A high output amplifier device comprising:
the output power stabilization circuit according to claim 6; and
a high-output amplifier for amplifying a high-frequency signal inputted from the input terminal and outputting the amplified high-frequency signal to the first variable attenuator, between the input terminal and the first variable attenuator.
